(19) United States
(12) Patent Application Publication
(10) Pub. No.: US 2026/0367181 A1
(43) Pub. Date: Nov. 19, 2026

(54) POWER MANAGEMENT DEVICE WITH POWER LOSS PROTECTION FUNCTION

(71) Applicant: Chengdu Monolithic Power Systems Co., Ltd., Chengdu (CN)

(72) Inventors: Hang Yang, Chengdu (CN); Li-Chen Cheng, New Taipei City (TW); Haitang Wang, Chengdu (CN); Pengjie Lai, Cupertino, CA (US); Bo Li, Chengdu (CN)

(21) Appl. No.: 19/680,817

(22) Filed: May 18, 2026

(30) Foreign Application Priority Data
May 19, 2025 (CN) 202510641278.5

(51) Int. Cl. G01R 31/52; H02J 7/60; H02J 7/68; H02J 7/80; H03K 5/19

(52) U.S. Cl. CPC G01R 31/52; H02J 7/663; H02J 7/68; H02J 7/80; H03K 5/19; H02J 2207/50

(57) ABSTRACT

A power management device, including an input terminal, a bus terminal, an energy storage terminal, a charging circuit, and a leakage current monitoring circuit. The input terminal is configured to receive an input voltage. The bus terminal is configured to provide a bus voltage. The energy storage terminal is configured to be coupled to a backup power device. The charging circuit is configured to charge the backup power device to maintain a voltage of the backup power device at a target voltage value. The leakage current monitoring circuit is configured to obtain a switching state of a switch in the charging circuit and determine whether leakage current of the backup power device is normal based on the switching state.

### CROSS-REFERENCE TO RELATED APPLICATIONS

The present application claims priority to, and the benefit of, Chinese Application No. 202510641278.5 filed on May 19, 2025, which is incorporated herein by reference in its entirety.

### TECHNICAL FIELD

The present invention generally relates to power supply devices, particularly but not limited to power management devices with power loss protection function.

### BACKGROUND

In certain existing power management systems, dual-power-supply architectures with power loss protection (PLP) are commonly employed for applications demanding stringent power continuity, such as enterprise-grade solid-state drives and data centers. When the primary power source suddenly fails or is interrupted, the system switches to the backup power source to maintain continuous power supply to the application device. For example, energy storage capacitors with higher rated voltages are commonly used as such backup power sources. These capacitors store energy during normal system operation and release the stored energy to continue powering the application device when the primary power source suddenly fails or is interrupted.

The leakage current of energy storage capacitors is subject to fluctuations driven by various internal and external factors. Degradation in the leakage current performance can render a capacitor unsuitable for backup power applications. Consequently, continuous monitoring of leakage current is critical to ensuring system reliability.

In existing power management technologies with power loss protection, periodic repeated charging and discharging of the energy storage capacitor is typically performed to minimize switching losses in the power switch. This causes the capacitor voltage to repeatedly rise and fall within a preset voltage range. Some leakage current monitoring methods often rely on the voltage characteristics of the energy storage capacitor during this periodic charging pattern. They assess the severity of leakage current by monitoring the duration of the charging cycle (e.g., the time taken for the capacitor voltage to rise from a first preset voltage to a second preset voltage) or the discharging cycle (e.g., the time taken for the capacitor voltage to fall from the second preset voltage to the first preset voltage).

However, for large-capacity capacitors (e.g., ultra-large electrolytic capacitors), achieving significant voltage changes during charging and discharging requires extremely high charging and discharging currents, resulting in substantial energy loss. Furthermore, frequent high-voltage charging and discharging cycles cause charge-discharge fatigue in electrolytic capacitors, thereby reducing their lifespan.

Therefore, it is necessary to propose an improved leakage current monitoring scheme to minimize the impact of leakage current monitoring actions on the normal functions of the power management device.

### SUMMARY

An embodiment of the present invention provides a power management device comprising an input terminal, a bus terminal, an energy storage terminal, a charging circuit, and a leakage current monitoring circuit. The input terminal is configured to receive an input voltage. The bus terminal is configured to provide a bus voltage. The energy storage terminal is configured to be coupled to a backup power device. The charging circuit is configured to charge the backup power device to maintain its voltage at a target voltage value. The leakage current monitoring circuit is configured to obtain a switching state of a switch in the charging circuit and determine whether a leakage current of the backup power device is normal based on the switching state.

Another embodiment of the present invention provides a monitoring method for monitoring leakage current of a backup power device, comprising: charging the backup power device using a charging circuit to maintain a voltage of the backup power device at a target voltage value; detecting a switching count of a switch in a switching circuit of the charging circuit within a monitoring period; and comparing the switching count with a standard range to determine whether the leakage current of the backup power device is normal.

It should be understood that the content described herein is not intended to identify key or essential features of the embodiments of the present invention, nor is it intended to limit the scope of the present invention. Other features of the present invention will become apparent from the following description.

### BRIEF DESCRIPTION OF DRAWINGS

For a better understanding of the present invention, embodiments of the invention will be described with reference to the accompanying drawings, which are provided for illustrative purposes only. The drawings typically show only partial features of the embodiments and are not necessarily drawn to scale.

FIG. 1 illustrates a block diagram of an application system with power loss protection function, according to an embodiment of the present invention.

FIG. 2 illustrates a circuit diagram of a power management device with leakage current monitoring function, according to an embodiment of the present invention.

FIG. 3 illustrates a functional block diagram of a leakage current monitoring circuit, according to an embodiment of the present invention.

FIGS. 4 and 5 exemplarily show waveforms of various signals within the power management device as leakage current from the energy storage capacitor changes, according to an embodiment of the present invention.

FIG. 6 illustrates a flowchart of a monitoring method for monitoring leakage current of a backup power device, according to an embodiment of the present invention.

### DETAILED DESCRIPTION

Various embodiments of the present invention will now be described. In the following description, certain specific details are included, such as exemplary circuits and exemplary values for these circuit components, to provide a thorough understanding of the embodiments. However, one skilled in the relevant art will recognize, that the disclosure can be performed without one or more of the specific details, or with other methods, components, materials, etc. In other instances, well-known structures, materials, processes or operations are not shown or described in detail to avoid obscuring aspects of the disclosure.

Throughout the specification and claims, the phrases “in an embodiment,” “in some embodiments,” “in an implementation,” and “in some implementations” used include combinations and sub-combinations of the various features described herein, as well as variations and modifications thereof. These phrases used herein do not necessarily refer to the same embodiment, although they may. It will be understood by those skilled in the art that the meanings of the above terms do not necessarily limit the terms, but merely provide illustrative examples for the terms. Note that when a component is “connected to” or “coupled to” another component, this means that the component is directly connected to or coupled to the other component, or indirectly connected to or coupled to the other component via another component. Particular features, structures or characteristics may be included in an integrated circuit, an electronic circuit, a combinational logic circuit or other suitable components that provide the described function. Furthermore, it should be understood that the drawings provided herewith are for explanation purposes to those of ordinary skill in the art and the drawings are not necessarily drawn to scale.

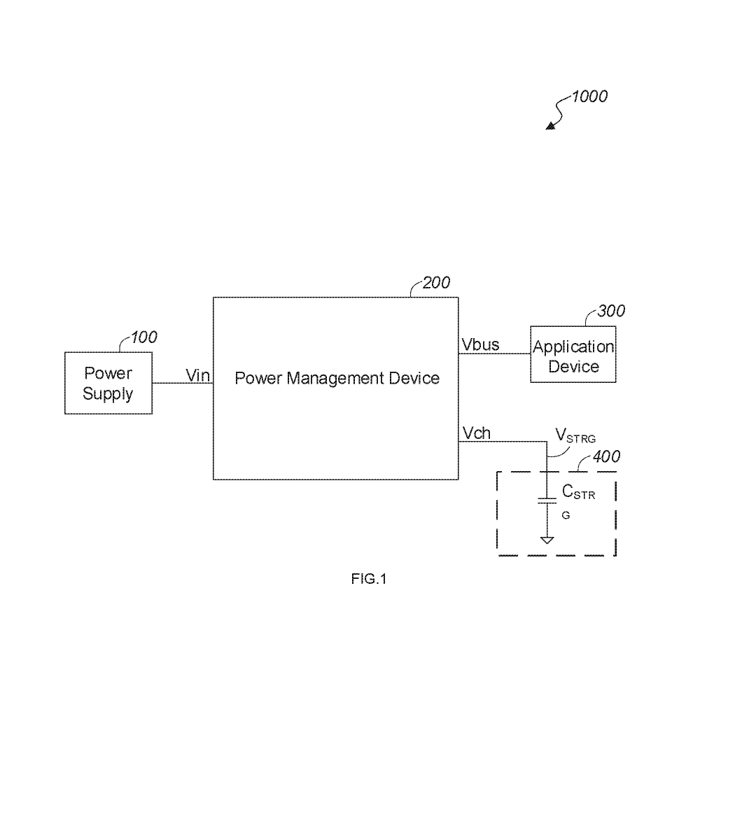

FIG. 1 illustrates a block diagram of an application system 1000 with a power loss protection function, according to an embodiment of the present invention. In the example shown in FIG. 1, the application system 1000 includes a power supply 100, a power management device 200, an application device 300, and a backup power device 400.

The power supply 100 includes any device or circuit capable of providing electrical energy to another circuit, such as a battery, a switching power supply, etc. In the example shown in FIG. 1, the power supply 100 may provide an input voltage Vin to the power management device 200, for example, the input voltage Vin is a DC voltage. It should be understood that the power supply 100 may also provide electrical energy in the form of current or power, and the present invention is not limited thereto.

The application device 300 may be, for example, an enterprise-class solid-state drive, a hard disk drive storage system, or any other device requiring a backup power device to provide power loss protection. During normal operation, the application device 300 utilizes a bus voltage Vbus provided by the power management device 200 as its primary power source. However, in the event of a sudden power loss (e.g., power failure of the input voltage Vin), the application device 300 can utilize the voltage provided by the backup power device 400 to complete ongoing operations or back up data.

The backup power device 400 may include at least one capacitor C_{STRG} (hereinafter referred to as an energy storage capacitor). For example, this energy storage capacitor C_{STRG} may be an electrolytic capacitor, a multilayer capacitor, a tantalum capacitor, a double-layer capacitor, or a polymer capacitor. In the embodiment shown in FIG. 1, the backup power device 400 is illustrated as comprising a single energy storage capacitor C_{STRG}. It should be understood that in other embodiments, the backup power device 400 may include multiple energy storage capacitors connected in series, in parallel, or in a series-parallel hybrid configuration.

The power management device 200 is configured to convert the input voltage Vin from the power supply 100 into the bus voltage Vbus during normal operation, for supply to the application device 300. Additionally, during normal operation, the power management device 200 may convert the input voltage Vin or the bus voltage Vbus into a charging voltage Vch and utilize the charging voltage Vch to charge the backup power device 400 (e.g., including the energy storage capacitor C_{STRG}) and maintain a voltage of the backup power device 400 at a target voltage value Vset. For example, in one exemplary application, the power management device 200 may boost a 12V input voltage Vin to a 35V charging voltage Vch to charge the backup power device 400. During an unexpected power loss event, the power management device 200 can convert energy stored in the backup power device 400 into the bus voltage Vbus and supply it to the application device 300. This enables the application device 300 to complete ongoing operations and perform tasks such as data backup. For example, in an exemplary application, the power management device 200 may reduce the voltage on the backup power device 400 (e.g., initially 35V, subsequently decreasing as the backup power device 400 discharges) to provide a 12V bus voltage Vbus to the application device 300.

In one embodiment, the power management device 200 may include a leakage current monitoring function to monitor leakage current in the backup power device 400. In one embodiment, the power management device 200 may send a warning signal to the user when the severity of the leakage current exceeds a tolerance threshold, enabling the user to promptly repair or replace the capacitors within the backup power device 400.

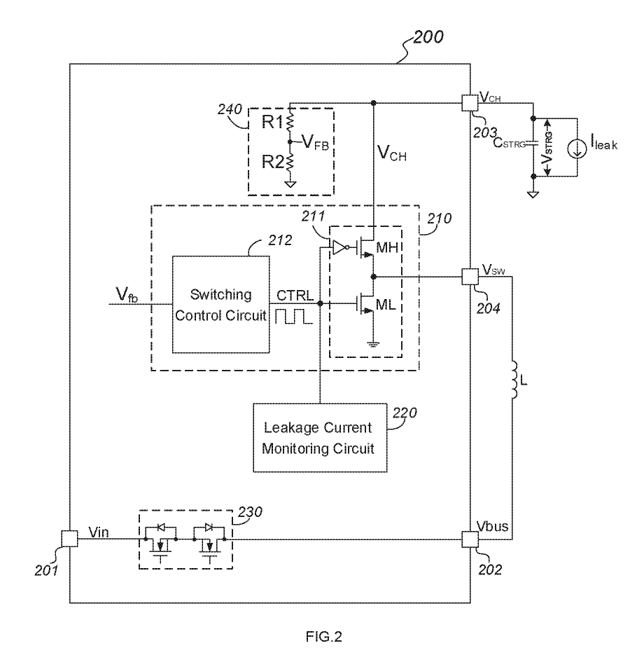

FIG. 2 illustrates a circuit diagram of a power management device 200 with power loss protection function, according to an embodiment of the present invention.

The power management device 200 may include multiple circuits and terminals packaged together as a power management integrated circuit (PMIC).

As shown in FIG. 2, the power management device 200 may include an input terminal 201, a bus terminal 202, an energy storage terminal 203, and a switching terminal 204. For simplicity, other terminals unrelated to the present invention are omitted from FIG. 2.

During normal operation of the power management device 200, the input voltage Vin from the input terminal 201 is connected to the bus terminal 202 to provide the bus voltage Vbus at the bus terminal 202.

In one embodiment, the power management device 200 may include an input protection circuit 230 coupled between the input terminal 201 and the bus terminal 202.In one embodiment, the input protection circuit 230 may include two transistors, such as two MOSFETs, connected such that their body diodes are back-to-back (hereinafter referred to as the back-to-back transistors for convenience). During normal operation, both back-to-back transistors are conductive, thereby connecting the input voltage Vin at input terminal 201 to the bus terminal 202 as bus voltage Vbus. Upon sudden power loss, both back-to-back transistors are turned off, disconnecting the input terminal 201 from the bus terminal 202. This prevents reverse current flow from the energy storage capacitor C_{STRG} back to a front-end device at the input terminal 201, thereby avoiding damage to the front-end device and minimizing additional power dissipation.

During normal operation of the power management device 200, leakage current (for example, shown as current source Ileak in FIG. 2) inevitably occurs in the energy storage capacitor C_{STRG}. For example, the current source Ileak may include leakage current from the energy storage capacitor C_{STRG} itself, leakage current at the energy storage terminal 203, and leakage current from other circuits associated with the energy storage capacitor C_{STRG}. These leakage currents vary due to various internal and external factors (e.g., capacitor open-circuit or short-circuit faults, capacitor lifespan, humidity and temperature of the capacitor's environment, etc.). Excessively high or low leakage currents may indicate that the energy storage capacitor C_{STRG} is in a faulty state and no longer suitable for continued operation as a backup power source. In one embodiment, the power management device 200 may include a charging circuit 210. During normal operation of the power management device 200, the charging circuit 210 converts the bus voltage Vbus into the charging voltage Vch to charge the energy storage capacitor C_{STRG} and maintain a voltage V_{STRG} on the energy storage capacitor C_{STRG} (or the voltage at the energy storage terminal 203) at a target voltage value Vset (e.g., 35V). That is, the charging circuit 210 supplements the charge loss caused by the leakage current Ileak by supplying electrical energy to the energy storage capacitor C_{STRG}. Furthermore, in another embodiment, the charging circuit 210 may also provide electrical energy for charging the storage capacitor C_{STRG} based on other voltages within the power management device 200 (e.g., the input voltage Vin). That is, it may convert other voltages into the charging voltage Vch to charge the storage capacitor C_{STRG}. The present invention is not limited thereto.

As shown in FIG. 2, the charging circuit 210 includes a switching circuit 211 and a switching control circuit 212. In one embodiment, the switching circuit 211 includes a switch MH (also referred to as a high-side switch) and a switch ML (also referred to as a low-side switch) connected in series between the energy storage terminal 203 and a reference ground. The switch MH, the switch ML, and an inductor L coupled between the switching terminal 204 and the bus terminal 202 form the power stage of a boost converter.

In one embodiment, as shown in FIG. 2, the switch MH and the switch ML in the switching circuit 211 each includes a controllable transistor. For example, FIG. 2 exemplarily illustrates these as metal-oxide-semiconductor field-effect transistors (MOSFETs). In the embodiment illustrated in FIG. 2, the switches MH and ML are implemented as NMOS transistors. In this configuration, the charging circuit 210 may further comprise a voltage lifting circuit (not shown) to ensure the proper conduction and biasing of switch MH. It should be noted, however, that the present disclosure is not limited to this specific implementation. For instance, the switches MH and ML may alternatively be implemented as PMOS transistors. For the sake of clarity, the following description assumes the use of NMOS transistors for both MH and ML.

Referring to FIG. 2, the switch ML in the switching circuit 211 includes a first terminal, a second terminal, and a control terminal. The first terminal of the switch ML is configured to be coupled to the switching terminal 204, the second terminal of the switch ML is configured to be coupled to the reference ground, and the control terminal of the switch ML is configured to receive the control signal CTRL from control circuit 212. The switch MH also includes a first terminal, a second terminal, and a control terminal. The first terminal of the switch MH is configured to be coupled to the first terminal of the switch ML. The second terminal of the switch MH is configured to be coupled to the energy storage terminal 203. The control terminal of the switch MH is used to receive the inverted signal of the control signal CTRL from the control circuit 212. A common connection terminal of the switches MH and ML is coupled to the switching terminal 204. The switches MH and ML can be turned on and off complementarily under the control of the control signal CTRL and its inverted signal, meaning only one of the two switches is conductive at any given time. In one embodiment, the control signal CTRL is a Pulse Width Modulation (PWM) signal. For example, in the embodiment shown in FIG. 2, when the control signal CTRL is at a logic high level, the switch MH is turned off and the switch ML is turned on, thereby energizing the inductor L via the bus voltage Vbus. During this phase, the inductor current increases. Conversely, when the control signal CTRL is at a logic low level, the switch MH is turned on and the switch ML is turned off, allowing the inductor L to discharge its stored energy. During this phase, the inductor current flowing through the inductor L decreases. By periodically controlling the switching operation of the switches MH and ML via the control signal CTRL, the bus voltage Vbus is converted into the charging voltage Vch to charge the energy storage capacitor C_{STRG}. In one embodiment, the energy storage terminal 203 may also be configured to be coupled to an output capacitor (not shown) for filtering and smoothing the charging voltage Vch. In another embodiment, since the energy storage capacitor C_{STRG} itself can filter and smooth the charging voltage Vch, an additional output capacitor may not be required.

In another embodiment, the switch ML is a controllable transistor, and the switch MH is a unidirectional conduction device (e.g., a diode). The control signal CTRL is provided to the controllable transistor ML to control its on/off. When the switch ML is turned on under the control of the signal CTRL, the switch MH is turned off. When the switch ML is turned off under the control of the signal CTRL, the switch MH is turned on. Therefore, in this case, the switch MH can also be considered to be turned on or off under the control of signal CTRL.

In the embodiment shown in FIG. 2, the charging circuit 210 operates in a boost mode. It should be understood that in applications where the preset voltage value of the energy storage capacitor C_{STRG} is lower than the bus voltage Vbus, the charging circuit 210 may also operate in a buck mode.

In one embodiment, the switching control circuit 212 may be configured to receive a feedback signal Vfb indicative of the voltage V_{STRG} of the energy storage capacitor C_{STRG} (or the voltage at the energy storage terminal 203), compare it with a reference voltage indicative of the target voltage value Vset, and generate the control signal CTRL for controlling the switches MH and ML.

As shown in FIG. 2, the power management device 200 may further include a feedback circuit 240 for providing the feedback signal Vfb indicative of the voltage V_{STRG} of the storage capacitor C_{STRG}. In the example of FIG. 2, the feedback circuit 240 is shown as being included within the PMIC 200. It should be understood that the feedback circuit 240 may also be configured externally to the PMIC 200.

In one embodiment, the switching control circuit 212 employs a frequency modulation scheme. For example, this frequency modulation scheme may be pulse frequency modulation (PFM). The switching control circuit 212 of the present invention may include any suitable control circuit that adjusts the frequency of the control signal CTRL based on the feedback signal Vfb, or simultaneously adjusts both the frequency and duty cycle. Examples include peak current control circuits, average current control circuits, constant on/off duration control circuits, and the like. The present invention imposes no restrictions on the topological structure of the switching control circuit 212.

According to an embodiment of the present invention, the power management device 200 may include a leakage current monitoring circuit 220 for monitoring a state of the leakage current Ileak. For example, the leakage current monitoring circuit 220 may be configured to receive a leakage current monitoring enable signal TEST_EN and enter a monitoring mode in response to the leakage current monitoring enable signal TEST_EN to commence leakage current monitoring operations. In one embodiment, the leakage current monitoring circuit 220 may periodically monitor the leakage current.

In one embodiment, the leakage current monitoring circuit 220 is configured to obtain a switching state of the switches (e.g., the switch MH and/or the switch ML) in the charging circuit 210, and to determine whether the leakage current Ileak of the backup power device 400 is normal based on the obtained switching state. As described earlier, during normal operation of the power management device 200 (i.e., when no sudden power supply failure occurs), the periodic switching operation of the switches (e.g., the switch MH and the switch ML) in the switching circuit 211 is controlled by the control signal CTRL. This maintains the voltage V_{STRG} at the stable predetermined voltage Vset and replenishes charge loss caused by leakage current Ileak. In other words, when leakage current increases, to continue maintaining the voltage V_{STRG} of the energy storage capacitor C_{STRG} at the predetermined voltage Vset, the charging circuit 210 needs to transfer more energy to the energy storage capacitor C_{STRG} per unit time. This manifests in variable frequency modulation schemes (e.g., Constant On Time (COT) control mode) as accelerated switching speed of the switches within the switching circuit. Similarly, when the leakage current decreases, the charging circuit 210 should transfer less energy per unit time to the energy storage capacitor C_{STRG}. This manifests in variable frequency modulation schemes as slowed switching speed of the switches within the switching circuit. Therefore, the aforementioned switching state of the switches may include their switching speed. In one embodiment, the leakage current monitoring circuit 220 is configured to detect a switching count of the power switches (e.g., ML and/or MH) within the charging circuit 210 over a predetermined monitoring period to determine a switching speed. In this context, the switching count represents the total number of switching operations (turned on or turned off) occurring within said monitoring period.

In one embodiment, the leakage current monitoring circuit 220 may further include a register (not shown) dedicated to recording the number of switch transitions within the monitoring period. In one embodiment, to obtain more stable monitoring results, the leakage current monitoring circuit 220 may be used to detect and record the number of switch transitions(i.e., switching counts) over a consecutive multiple (e.g., N, where N is an integer greater than 1) of monitoring periods, and then calculate the average of the switching counts across these multiple monitoring periods to obtain the average switching count.

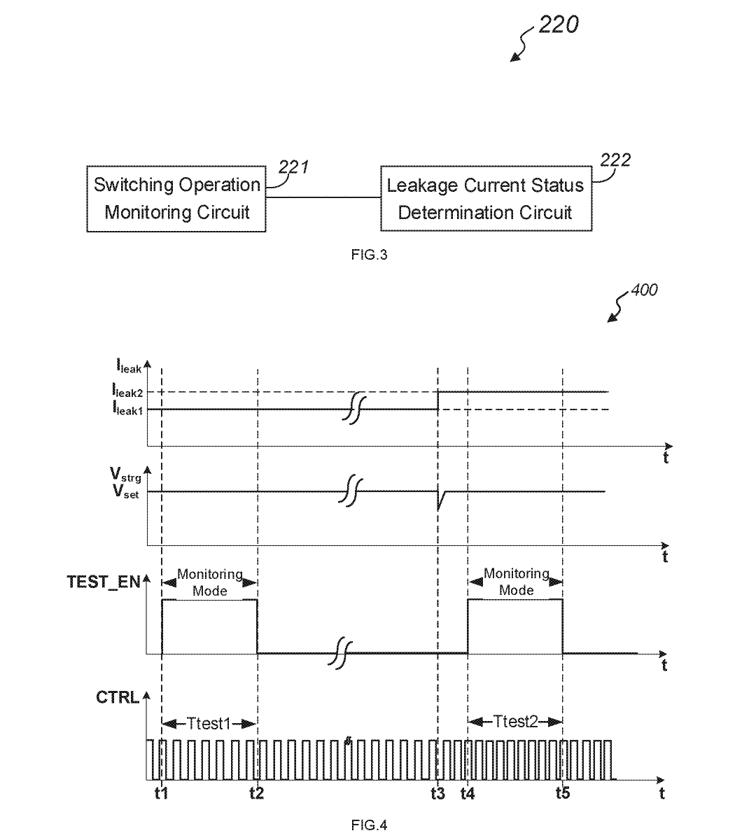

Referring to FIG. 3, the leakage current monitoring circuit 220 may include a switching operation monitoring circuit 221 and a leakage current status determination circuit 222. The switching operation monitoring circuit 221 may be used to obtain the number of switching operations (i.e., switching counts) within one or more monitoring periods. The leakage current status determination circuit 222 may be used to calculate the average of the obtained switching counts and compare the average switching count with a standard range to determine whether the leakage current of the backup power device is normal. In one embodiment, when the average switching count exceeds the standard range, the leakage current is determined to be abnormal; when the average switching count falls within the standard range, the leakage current is determined to be normal. For example, in an actual application, the standard range is 18,000 to 22,000. When the average switching count falls within the standard range (e.g., greater than 18,000 and less than 22,000), the leakage current Ileak can be considered normal. If the switching count falls outside the standard range (e.g., less than 18,000 or greater than 22,000), the leakage current Ileak is deemed abnormal. The leakage current status determination circuit 222 can compare the average switching count with the median (e.g., 20,000, which may also be referred to as a reference count) of the standard range to determine whether the difference between the average switching count and this median exceeds a preset percentage. In an exemplary application, this set percentage may be ±10%. For instance, when the difference between the average switching count and the median exceeds the preset percentage, the average switching count can be determined to be outside the standard range. In one embodiment, this reference count may be set by the user according to the actual application. Additionally, the user can adjust the aforementioned standard range by modifying the aforementioned set percentage.

According to an embodiment of the present invention, since the switch (e.g., MH or ML) in the switching circuit 211 is turned on or off under the control of the control signal CTRL, the switching speed of the switch can also be indicated by the frequency of the control signal CTRL. In one embodiment, the aforementioned switching operation monitoring circuit 221 may include a pulse detection circuit for detecting rising/falling edges of pulses in the control signal CTRL within a monitoring period and counting a number of the pulse rising/falling edges to obtain the switching counts within the monitoring period. The pulse detection circuit may employ any circuit structure suitable for detecting and counting pulse signals, and the present invention is not limited thereto.

In one embodiment, the leakage current monitoring circuit 220 may further include a dedicated register (not shown) for recording that the leakage current Ileak is abnormal. When the average switching count exceeds the standard range, a bit value in this register may be set to a first value (e.g., 1). In one embodiment, the power management device 200 may further include a communication module (not shown) and a communication port (not shown) for sending an indication signal to the user that the leakage current Ileak is abnormal in response to the bit value in the register being set to the first value, enabling the user to promptly repair or replace the capacitor in the backup power device 400. The communication protocols supported by the communication module include but are not limited to the Universal Asynchronous Receiver-Transmitter (UART) protocol, the Serial Peripheral Interface (SPI) protocol, and the Inter-Integrated Circuit (I2C) protocol. The present invention is not limited to these protocols.

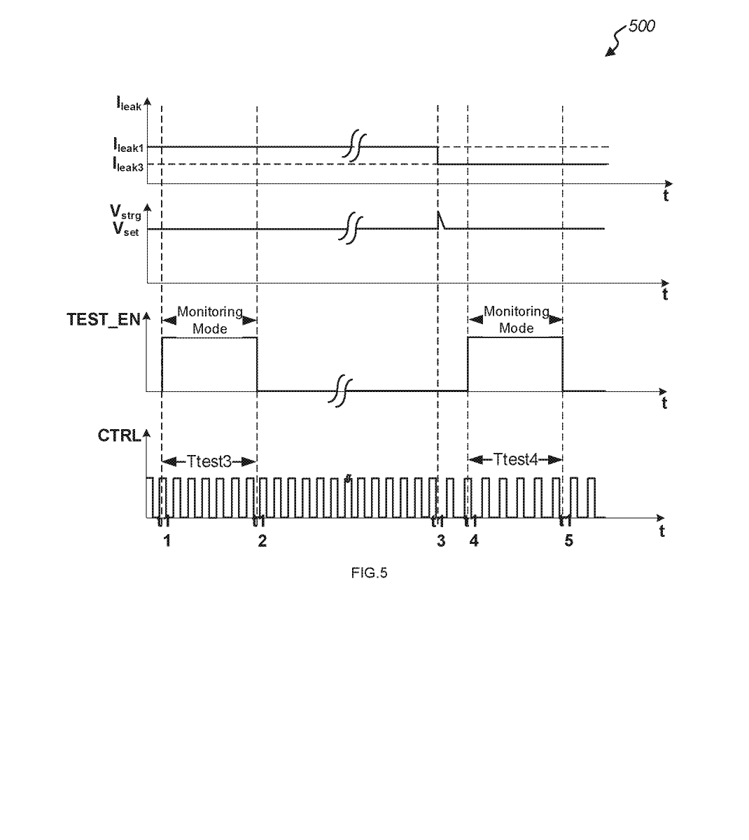

FIGS. 4 and 5 exemplarily illustrate waveforms of various signals within the power management device 200 as the leakage current Ileak of the storage capacitor C_{STRG} changes, according to an embodiment of the present invention. FIGS. 4 and 5 will be described with reference to FIGS. 1-3. In this embodiment, the description uses the charging circuit 210 operating in a constant on-time control mode (COT) as an example.

For ease of description, FIGS. 4 and 5 illustrate a step-wise change in the leakage current Ileak. FIG. 4 illustrates a sudden increase in the leakage current Ileak from Ileak1 to Ileak2. FIG. 5 illustrates a scenario where the leakage current Ileak suddenly decreases from Ileak1 to Ileak3. For example, the changes depicted in FIGS. 4 and 5 may result from leakage current slowing down or accelerating due to an open-circuit event in the energy storage capacitor C_{STRG}.

It should be understood that in practical usage scenarios, besides sudden events (e.g., faults or abrupt changes in environment or operating conditions) causing step-wise changes in the leakage current Ileak, the leakage current Ileak may also undergo gradual changes due to natural aging of capacitor components. When such gradual changes accumulate beyond the tolerance range, the leakage current Ileak detection scheme according to the embodiments of the present invention can similarly detect abnormal leakage current.

As shown in FIG. 4, at time t1, the leakage current monitoring enable signal TEST_EN transitions to a high level, allowing the leakage current monitoring circuit 220 to enter monitoring mode to perform leakage current monitoring operations. These monitoring operations may include monitoring the switching count of a switch (e.g., switch ML or switch MH) in the switching circuit. For instance, since the switching circuit is turned on or off under the control of the control signal CTRL, the number of switching operations can be obtained by counting the number of rising/falling edges of the control signal CTRL. After the monitoring period Ttest1 ends, i.e., at time t2, the leakage current monitoring enable signal TEST_EN goes low, allowing the leakage current monitoring circuit 220 to exit monitoring mode. In one embodiment, the leakage current monitoring circuit 220 may detect and record the number of switch transitions/switching counts (or the number of rising/falling edge pulses) over a continuous plurality of monitoring periods. It then calculates the average of the switching counts (or rising/falling edge pulse counts) across these periods to yield a valid monitoring result. It should be understood that FIG. 4 is merely a schematic diagram drawn for ease of understanding, and does not impose any restrictions on the amplitude, quantity, or relative magnitude of the various signals. For example, in the illustrated example of FIG. 4, the number of pulses in the control signal during the monitoring period Ttest1 is only 6, whereas in actual application scenarios, the number of pulses in the control signal during detection cycle Ttest1 may reach 20,000.

At time t3, the leakage current Ileak increases from Ileak1 to Ileak2. At this point, due to the response delay of the charging circuit 210, its output voltage (e.g., also equivalent to the voltage V_{STRG} of the storage capacitor C_{STRG}) experiences a voltage sag. Subsequently, after a certain period, the voltage V_{STRG} recovers to the predetermined voltage Vset. Due to the increased leakage current, to maintain the voltage V_{STRG} of the energy storage capacitor C_{STRG} at the preset voltage Vset, the charging circuit210 need to transfer more energy to the energy storage capacitor C_{STRG} per unit time. In variable frequency modulation schemes (e.g., the constant on-time control mode), this manifests as an accelerated switching speed of the switching circuit or an increased frequency of the control signal CTRL.

At time t4, the leakage current monitoring enable signal TEST_EN transitions to a high level. The leakage current monitoring circuit 220 enters monitoring mode in response to the leakage current monitoring enable signal TEST_EN and begins executing leakage current monitoring operations. After the monitoring period Ttest2 concludes at time t5, the leakage current monitoring enable signal TEST_EN transitions to a low level, and the leakage current monitoring circuit 220 exits monitoring mode. For example, in the illustration shown in FIG. 4, the number of pulses in the control signal increases to 9 during the monitoring period Ttest2. Similarly, it should be understood that the 9 pulses shown in FIG. 4 are provided merely as an example; in actual application scenarios, the number of pulses in the control signal CTRL during the detection cycle Ttest2 may reach 30,000.

FIG. 5 exemplarily illustrates waveforms of various signals during operation of the power management device 200 as the leakage current Ileak of the storage capacitor C_{STRG} decreases, according to an embodiment of the present application. For brevity, descriptions of elements identical to those in FIG. 4 are omitted in FIG. 5. In the embodiment shown in FIG. 5, at time t3, the leakage current Ileak decreases from Ileak1 to Ileak3. Due to the decrease in the leakage current, to maintain the voltage V_{STRG} of the storage capacitor C_{STRG} at the predetermined voltage Vset, the charging circuit 210 must transfer less energy to the storage capacitor C_{STRG} per unit time. In variable frequency modulation schemes (e.g., constant on-time control mode), this manifests as a decrease in the frequency of control signal CTRL or a reduction in the switching speed of the switching circuit. For example, during monitoring period Ttest3, the number of pulses in the control signal is 6, whereas during monitoring period Ttest4, the number of pulses in the control signal decreases to 5. Similarly, the 6 and 5 pulses shown in FIG. 5 are merely illustrative; in actual applications, the control signal may have 18,000 pulses during test period Ttest3 and 16,000 pulses during test period Ttest4.

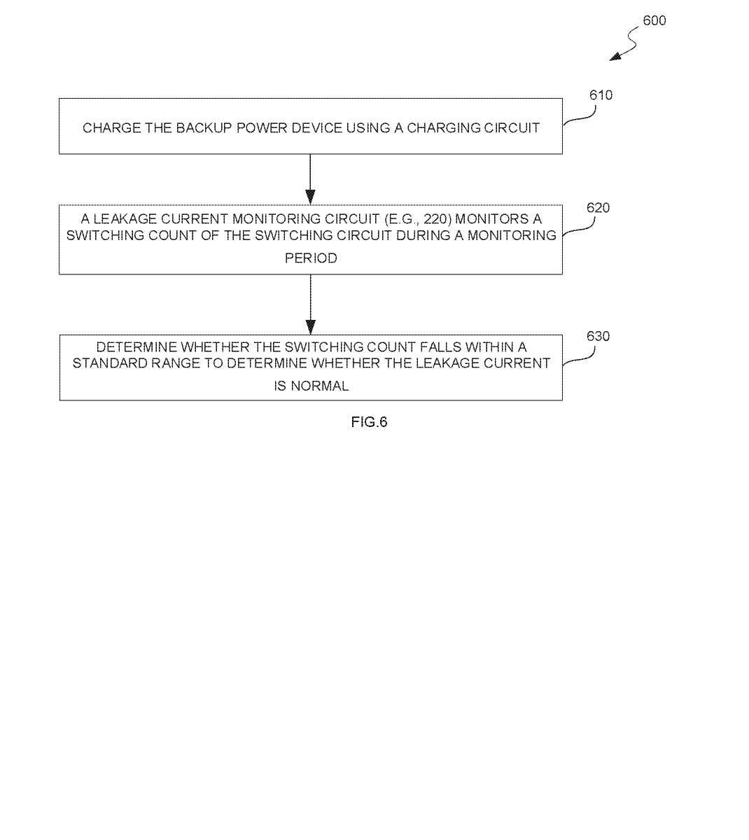

FIG. 6 illustrates a flowchart of monitoring method 600 for monitoring leakage current of a backup power device (e.g., 400), according to an embodiment of the present invention. FIG. 6 will be described in conjunction with FIGS. 1-5. Monitoring method 600 may include the following steps 610 to 630.

Step 610: Charge the backup power device using a charging circuit (e.g., 210). As described earlier, the backup power device may comprise multiple energy storage capacitors connected in series, in parallel, or in a series-parallel hybrid configuration. For example, the charging circuit may include a switching control circuit (e.g., 212) and a switching circuit (e.g., 211). The charging circuit may control the switching operation of switches (e.g., the switch MH and the switch ML) within the switching circuit using a control signal CTRL, thereby maintaining the voltage of the backup power device at a stable predetermined voltage Vset. For example, the control signal CTRL may be a PWM signal.

Step 620: A leakage current monitoring circuit (e.g., 220) monitors a switching count of a switch in the switching circuit during a monitoring period. For example, the witching counts during the monitoring period can be obtained by monitoring the rising/falling edges of the control signal CTRL.

Step 630: Determine whether the switching count falls within a standard range to determine whether the leakage current Ileak is normal. For example, a leakage current status determination circuit (e.g., 222) may compare the switching count with a reference count and determine whether the difference between the switching count and the reference count exceeds a set percentage. When the difference between the switching count and the reference count exceeds the set percentage, the leakage current is determined to be abnormal.

The power management device with power loss protection proposed in the embodiments of the present invention is configured to maintain the voltage of the backup power device at the stable set voltage and compensate for charge loss caused by leakage current by controlling the switching speed of the power switch. The leakage current monitoring scheme according to the embodiments of the present invention achieves leakage current monitoring by monitoring the switching speed of the power switch, which is simpler and more efficient compared to traditional monitoring schemes that involve repeated charging and discharging of the energy storage capacitor. Furthermore, the leakage current monitoring scheme of the present invention avoids subjecting the supercapacitor to charge-discharge cycles that cause significant voltage fluctuations. This approach prevents energy loss during charging, avoids battery damage from frequent charge-discharge cycles, and minimizes the impact of monitoring actions on normal function.

Those skilled in the art will appreciate that the present invention is not limited to the specific embodiments illustrated and described herein. Rather, the scope of the invention is defined by the appended claims and includes combinations and subcombinations of the various features described above, as well as variations and modifications that would occur to those skilled in the art upon reading the foregoing description and that are not within the scope of the prior art.

1. A power management device, comprising:
an input terminal, configured to receive an input voltage;
a bus terminal, configured to provide a bus voltage;
an energy storage terminal, configured to be coupled to a backup power device;
a charging circuit, configured to charge the backup power device to maintain a voltage of the backup power device at a target voltage value; and
a leakage current monitoring circuit, configured to obtain a switching state of a switch in the charging circuit and determine whether a leakage current of the backup power device is normal based on the switching state.

2. The power management device according to claim 1, wherein the backup power device comprises at least one capacitor.

3. The power management device according to claim 1, wherein the switching state includes a switching speed of the switch.

4. The power management device according to claim 3, wherein the leakage current monitoring circuit is configured to: detect a switching count of the switch within each of M monitoring periods to obtain M switching counts, and to calculate an average of the M switching counts to obtain an average switching count, wherein the average switching count is used to indicate the switching state, and wherein M is an integer greater than or equal to 1.

5. The power management device according to claim 1, wherein the leakage current monitoring circuit is configured to compare the switching state with a standard range to determine whether the leakage current of the backup power device is normal.

6. The power management device according to claim 1, wherein the charging circuit is coupled between the bus terminal and the energy storage terminal to convert the bus voltage into a charging voltage for charging the backup power device.

7. The power management device according to claim 6, wherein the charging circuit comprises a switching circuit and a switching control circuit, wherein the switching control circuit is configured to provide a control signal to control on and off of the switch in the switching circuit to increase or decrease an inductor current flowing through a power inductor, thereby converting the bus voltage into the charging voltage.

8. The power management device according to claim 7, wherein the switching control circuit is configured to generate the control signal based on a feedback voltage indicative of a voltage on the energy storage terminal and a reference voltage indicative of the target voltage value, to maintain the voltage on the energy storage terminal at the target voltage value.

9. The power management device according to claim 7, wherein the switching control circuit is configured to operate in a variable frequency modulation mode.

10. The power management device according to claim 9, wherein the variable frequency modulation mode includes a constant on-time (COT) control mode.

11. The power management device according to claim 7, wherein the switching circuit comprises a high-side switch and a low-side switch connected in series between the energy storage terminal and a reference ground, wherein the high-side switch and the low-side switch are turned on and off complementarily under control of the control signal.

12. The power management device according to claim 11, wherein the leakage current monitoring circuit is configured to detect the switching state of the low-side switch.

13. The power management device according to claim 4, wherein the leakage current monitoring circuit comprises:
a pulse detection circuit, configured to detect rising/falling edges of a control signal used to control the switch in the switching circuit within each of the M monitoring periods, counting the rising/falling edges, and thereby obtaining the M switching counts within the M monitoring periods based on the number of rising/falling edges; and
a leakage current status determination circuit, which averages M switching counts to obtain the average switching count, and compares the average switching count with a standard range to determine whether the leakage current status is normal.

14. The power management device according to claim 13, wherein when the average switching count exceeds the standard range, the leakage current is determined to be abnormal, and when the average switching count falls within the standard range, the leakage current is determined to be normal.

15. The power management device according to claim 11, further comprising a switching terminal configured to be coupled to a common connection node of the high-side switch and the low-side switch, wherein the leakage current monitoring circuit comprises:
a pulse detection circuit, configured to detect rising/falling edges of pulses on the switching terminal during M monitoring periods and counting the rising/falling edges to obtain M switching counts based on the number of rising/falling edges in each of the M monitoring periods; and
a leakage current status determination circuit, configured to average the switching counts over the M monitoring periods to obtain an average switching count, and comparing the average switching count with a standard range to determine whether the leakage current status is normal.

16. The power management device according to claim 1, wherein the leakage current monitoring circuit further comprises a register for recording whether the leakage current is normal, and wherein the leakage current monitoring circuit is configured to set a bit value of the register to a first value in response to the leakage current being determined to be abnormal.

17. The power management device according to claim 16, further comprising a communication module and a communication interface for transmitting an alarm signal in response to the bit value of said register being set to the first value.

18. The power management device according to claim 1, further comprising the backup power device.

19. A monitoring method for monitoring leakage current of a backup power device, comprising:
charging the backup power device using a charging circuit to maintain a voltage of the backup power device at a target voltage value;
detecting a switching count of a switching circuit within the charging circuit during a monitoring period; and
comparing the switching count with a standard range to determine whether the leakage current of the backup power device is normal.

20. The method according to claim 19, wherein the charging circuit comprises the switching circuit which is turned on and off under control of a control signal, wherein detecting the switching count of the switching circuit in the charging circuit during the monitoring period comprises:
detecting rising/falling edges of pulses in the control signal within the monitoring period, counting a number of the rising/falling edges, and obtaining the switching count of the switch in the switching circuit based on the number of rising/falling edges.
